(19) United States
(12) Patent Application Publication
(10) Pub. No.: US 2026/0036211 A1
(43) Pub. Date: Feb. 5, 2026

(54) GATE VALVE ASSEMBLIES, REACTOR SYSTEMS INCLUDING GATE VALVE ASSEMBLIES, AND METHODS OF PERFORMING PARALLEL OPERATIONS WITHIN GATE VALVE ASSEMBLIES

(71) Applicant: ASM IP Holding B.V., Almere (NL)

(72) Inventors: Samer Banna, Phoenix, AZ (US); Kyle Tantiwong, Scottsdale, AZ (US)

(21) Appl. No.: 19/281,823

(22) Filed: Jul. 28, 2025

Related U.S. Application Data
(60) Provisional application No. 63/677,863, filed on Jul. 31, 2024.

(51) Int. Cl. F16K 3/02; H01L 21/67

(52) U.S. Cl. CPC F16K 3/029; F16K 3/0218; F16K 3/0272; H01L 21/67017

(57) ABSTRACT

Gate valve assemblies, reactor systems including gate valve assemblies, and methods of performing parallel operation within a gate valve assembly are disclosed. The gate valve assemblies disclosed include a gate valve block body configured for receiving a first sealing member and a second sealing member. The reactor systems disclosed include a back-end transfer module, a process module, and a gate valve assembly, including first and second sealing members. The methods of performing parallel operation within a gate valve assembly disclosed include transferring a substrate through a passthrough within a gate valve assembly while sensing one or more properties of the substrate.

### CROSS-REFERENCE TO RELATED APPLICATION(S)

This application claims the benefit of U.S. Provisional Application 63/677,863 filed on Jul. 31, 2024, the entire contents of which are incorporated herein by reference.

### FIELD

The present disclosure generally relates to the field of semiconductor processing assemblies, systems, and methods, and to the field of device and integrated circuit manufacture. More particularly, the present disclosure relates to gate valve assemblies configured for receiving a first sealing member and a second sealing member, as well as reactor systems including such gate valve assemblies and associated methods for performing parallel operations within gate valve assemblies.

### BACKGROUND

Semiconductor devices and integrated circuits are typically fabricated on a substrate of semiconductor material, often referred to as a substrate, wafer, and/or workpiece. Processing methods commonly used in the fabrication of semiconductor devices and integrated circuits include, but are not limited to, vapor deposition processes (e.g., atomic layer deposition, chemical vapor deposition, etc.) and etching processes (e.g., chemical vapor etching, atomic layer etching, plasma-based etching etc.). These processes generally involve forming or removing a layer of material on/from an exposed surface of the substrate. The parameters governing such processes are commonly tightly controlled to ensure that each substrate subjected to a particular process has substantially the same amount of material added or removed.

In some semiconductor manufacturing processes, substrates are transported between different regions of a reactor system through gate valve assemblies. For example, substrates can be transported from a back-end transfer module through a gate valve assembly to a process module for processing. Once a process is complete in one process module, the substrate can be transferred to a different process module to continue processing the substrate. During the transfer of a substrate between different process modules the substrate can pass through one or more gate valve assemblies multiple times. Such gate valve assemblies typically employ a single gate valve device including an actuator operably connected to a sealing member by an actuating member. However, there remains a need for improved gate valve assemblies which can, for example, house two gate valve devices in a serial configuration (referred to herein as a dual gate valve configuration. Such a dual gate valve configuration can simplify manufacturing, assembly, and maintenance of a reactor system. In addition, gate valve assemblies with additional functionality are desirable to further improve performance of a reactor system associated with such gate valve assemblies.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In accordance with examples of the disclosure a gate valve assembly is provided including a gate valve block body including a first face with a first lateral aperture, a second face longitudinally spaced apart from the first face and having a second lateral aperture, an intermediate member disposed between the first face and the second face, the intermediate member having a third lateral aperture; a block body floor extending between the first face and the second face, wherein the intermediate member intersects the block body floor, and wherein the first face, the intermediate member and the block body floor at least partially define a first valve seat and the second face, the intermediate member and the block body floor at least partially define a second valve seat; a first aperture disposed in the first valve seat and configured for receiving a first actuating member of a first gate valve actuator; a second aperture disposed in the second valve seat and configured for receiving a second actuating member of a second gate valve actuator; and a passthrough extending through the gate valve block body and coupling the first lateral aperture to the third lateral aperture and the second lateral aperture; wherein the gate valve block body comprises a singular gate valve block body which extends monolithically between the first face of the gate valve block body and the second face of the gate valve block body.

In some embodiments the gate valve assembly further comprises a flange assembly coupled to the first face of the gate valve block body, the flange assembly configured to couple the gate valve block body with a process module of a reactor system.

In some embodiments the gate valve assembly further comprises a first service channel disposed between an upper portion of the first face and the intermediate member and a second service channel disposed between an upper portion of the second face and the intermediate member.

In some embodiments the gate valve assembly further comprises a first removable service cover extending between an upper surface of the first face and an upper surface of the intermediate member and enclosing an upper extent of the first service channel, and a second removable service cover extending between an upper surface of the second face and the upper surface of the intermediate member and enclosing an upper extent of the second service channel.

In some embodiments the gate valve assembly further comprises one or more sensor assemblies each aligned with at least one of the first service channel and the second service channel and configured for sensing a substrate property as a substrate traverses the passthrough between the first lateral aperture and the second lateral aperture. In some embodiments the one or more sensor assemblies comprise an automatic substrate centering sensor configured to detect misalignment of a substrate as a substrate traverses the passthrough. In some embodiments the one or more sensor assemblies comprise a substrate deformation sensor configured to detect substrate bow as a substrate traverses the passthrough.

In some embodiments at least one of the one or sensor assemblies is positioned internally within at least one of the first service channel and the second service channel.

In some embodiments at least one of the one or more sensor assemblies is positioned externally on at least one of a top surface of the first removable service cover and a top surface of the second removable service cover.

In some embodiments at least one of the first removable service cover and the second removable service cover comprises a view port, wherein the view port comprises an optically transparent material having optical transparency over at least a portion of a wavelength that is emitted and/or received by one of the sensor assemblies.

In some embodiments the gate valve assembly further comprises a first sealing member arranged within the first valve seat and having a first closed position, whereat the first sealing member separates the first lateral aperture from the second lateral aperture, and a first open position, whereat the first lateral aperture is fluidly coupled to the second valve seat; the first gate valve actuator being operably connected to the first sealing member by the first actuating member and configured to move the first sealing member between the first open position and the first closed position by movement of the first actuating member through the first aperture.

In some embodiments the gate valve assembly further comprises a second scaling member arranged within the second valve seat and having a second closed position, whereat the second sealing member separates the first lateral aperture from the second lateral aperture, and a second open position, whereat the first valve seat is fluidly coupled to the second lateral aperture; the second gate valve actuator operably being connected to the second sealing member and configured to move the second sealing member between the second open position and the second closed position by movement of the second actuating member through the second aperture.

In accordance with examples of the disclosure a reactor system is provided including a back-end transfer module; a process module; and a gate valve assembly disposed between and coupled with the back-end transfer module and the process module, the gate valve assembly including: a gate valve block body comprising: a first face with a first lateral aperture; a second face longitudinally spaced apart from the first face and having a second lateral aperture; an intermediate member disposed between the first face and the second face, the intermediate member having a third lateral aperture; a block body floor extending between the first face and the second face, wherein the intermediate member intersects the block body floor, and wherein the first face, the intermediate member and the block body floor at least partially define a first valve seat and the second face, the intermediate member and the block body floor at least partially define a second valve seat. In some embodiments the gate valve assembly of the reactor system further comprises a first aperture disposed in the first valve seat and configured for receiving a first actuating member of a first gate valve actuator; a second aperture disposed in the second valve seat and configured for receiving a second actuating member of a second gate valve actuator; and a passthrough extending through the gate valve block body and coupling the first lateral aperture to the third lateral aperture and the second lateral aperture; a first sealing member arranged within the first valve seat and having a first closed position, whereat the first sealing member separates the first lateral aperture from the second lateral aperture, and a first open position, whereat the first lateral aperture is fluidly coupled to the second valve seat; the first gate valve actuator operably connected to the first sealing member by the first actuating member and configured to move the first sealing member between the first open position and the first closed position by movement of the first actuating member through the first aperture; a second sealing member arranged within the second valve seat and having a second closed position, whereat the second sealing member separates the first lateral aperture from the second lateral aperture, and a second open position, whereat the first first valve seat is fluidly coupled to the second lateral aperture; and the second gate valve actuator operably connected to the second sealing member and configured to move the second sealing member between the second open position and the second closed position by movement of the second actuating member through the second aperture; and a flange assembly coupled to the first face of the gate valve block body, the flange assembly configured to couple the gate valve block body with the process module; wherein the gate valve block body comprises a singular gate valve block body which extends monolithically between the first face of the gate valve block body and the second face of the gate valve block body.

In some embodiments the reactor system further comprises a first service channel disposed between an upper portion of the first face and the intermediate member and a second service channel disposed between an upper portion of the second face and the intermediate member.

In some embodiments the reactor system further comprises a first removable service cover extending between an upper surface of the first face and an upper surface of the intermediate member and enclosing an upper extent of the first service channel, and a second removable service cover extending between an upper surface of the second face and the upper surface of the intermediate member and enclosing an upper extent of the second service channel.

In some embodiments the reactor system further comprises one or more sensor assemblies each aligned with at least one of the first service channel and the second service channel and configured for sensing a substrate property as substrate traverses the passthrough disposed between the first lateral aperture and the second lateral aperture.

In some embodiments the one or more sensor assemblies comprise an automatic substrate centering sensor configured to detect substrate misalignment as a substrate traverses the passthrough.

In some embodiments the one or more sensor assemblies comprise a substrate deformation sensor configured to detect substrate bow as a substrate traverses the passthrough.

In accordance with examples of the disclosure a method of performing parallel operations within a gate valve assembly including one or more sensor assemblies is provided, the method comprising: at the gate valve assembly disposed between and coupled with a back-end transfer module and a process module, the gate valve assembly comprising a singular gate valve block body comprising: a first face with a first lateral aperture; a second face longitudinally spaced apart from the first face and having a second lateral aperture; an intermediate member disposed between the first face and the second face, the intermediate member having a third lateral aperture; a block body floor extending between the first face and the second face, wherein the intermediate member intersects the block body floor, and wherein the first face, the intermediate member and the block body floor at least partially define a first valve seat and the second face, the intermediate member and the block body floor at least partially define a second valve seat; a first aperture disposed in the first valve seat and configured for receiving a first actuating member of a first gate valve actuator; a second aperture disposed in the second valve seat and configured for receiving a second actuating member of a second gate valve actuator; and a passthrough extending through the singular gate valve block body and coupling the first lateral aperture to the third lateral aperture and the second lateral aperture.

In some embodiments the method further comprises moving a first sealing member arranged within the first valve seat and from a first closed position, whereat the first sealing member separates the first lateral aperture from the second lateral aperture, to a first open position, whereat the first lateral aperture is fluidly coupled to the second valve seat, wherein the first gate valve actuator is operably connected to the first sealing member by the first actuating member and is configured to move the first sealing member from the first closed position to the first closed position by movement of the first actuating member through the first aperture.

In some embodiments the method further comprises moving a second sealing member arranged within the second valve seat and from a second closed position, whereat the second sealing member separates the first lateral aperture from the second lateral aperture, to a second open position, whereat the first lateral aperture is fluidly coupled to the second valve seat, wherein the second gate valve actuator is operably connected to the second sealing member by the second actuating member and is configured to move the second sealing member from the second closed position to the second closed position by movement of the second actuating member through the second aperture.

In some embodiments the method further comprises transferring a substrate through the passthrough disposed within the singular gate valve block body between the first lateral aperture and the second lateral aperture.

In some embodiments the method further comprises sensing a property of the substrate in parallel with transferring the substrate by employing the one or more sensor assemblies which are each aligned with at least one of a first service channel disposed between an upper portion of the first face and the intermediate member and a second service channel disposed between an upper portion of the second face and the intermediate member.

In some embodiments the one or more sensor assemblies comprise an automatic substrate centering sensor configured to detect substrate misalignment.

In some embodiments the one or more sensor assemblies comprise a substrate deformation sensor configured to detect substrate bow.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a reactor system in accordance with one or more embodiments of the disclosure.

FIG. 2 illustrates a cross-sectional view of a portion of a reactor system including a gate valve assembly in accordance with one or more embodiments of the disclosure.

FIG. 3 illustrates an additional cross-sectional view of a portion of a reactor system including a gate valve assembly in accordance with one or more embodiments of the disclosure.

FIG. 4 illustrates a perspective view of a gate valve block body in accordance with one or more embodiments of the disclosure.

FIG. 5 illustrates an additional perspective view of a gate valve block body in accordance with one or more embodiments of the disclosure.

FIG. 6 illustrates a cross-sectional view of a gate valve block body in accordance with one or more embodiments of the disclosure.

FIG. 7 illustrates an expanded cross-sectional view of a portion of a reactor system including a gate valve assembly in accordance with one or more embodiments of the disclosure.

FIG. 8 illustrates a method of performing parallel operations within a gate valve assembly in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of assemblies, systems, and methods provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

Various embodiments of the present disclosure relate to gate valve assemblies configured for receiving and operating two gate valve devices (i.e., a dual gate valve configuration). In such embodiments the gate valve assemblies can comprise a gate valve block body fabricated from a singular block body, e.g., a singular metallic block. Such gate valve assemblies including a singular block body can simplify the operation, maintenance, and manufacture of the gate valve assemblies. In addition, the gate valve assemblies of the present disclosure can include integrated sensor assemblies that allow for monitoring and/or control of substrates as they are transferred through the gate valve assemblies. Common sensor system for measuring various properties of a substrate during the manufacture of semiconductor devices and integrated circuits are positioned remotely from the reactor system performing the manufacturing process (i.e., ex-situ measurements). In contrast, the gate valve assemblies of the present disclosure can include integrated sensor assemblies configured for monitoring and/or controlling the properties of a substrate within the reactor system (e.g., in-situ measurements). For example, substrate measurements can be performed in-between process operations in the various process modules of a cluster-type platform as the substrate is transferred in and out of the process modules through the gate valve assemblies including the sensor assemblies. The gate valve assemblies of the present disclosure therefore allow substrate measurements to be taken immediately upon transfer into and out of the process modules thereby permitting more accurate determination of the status of the substrate.

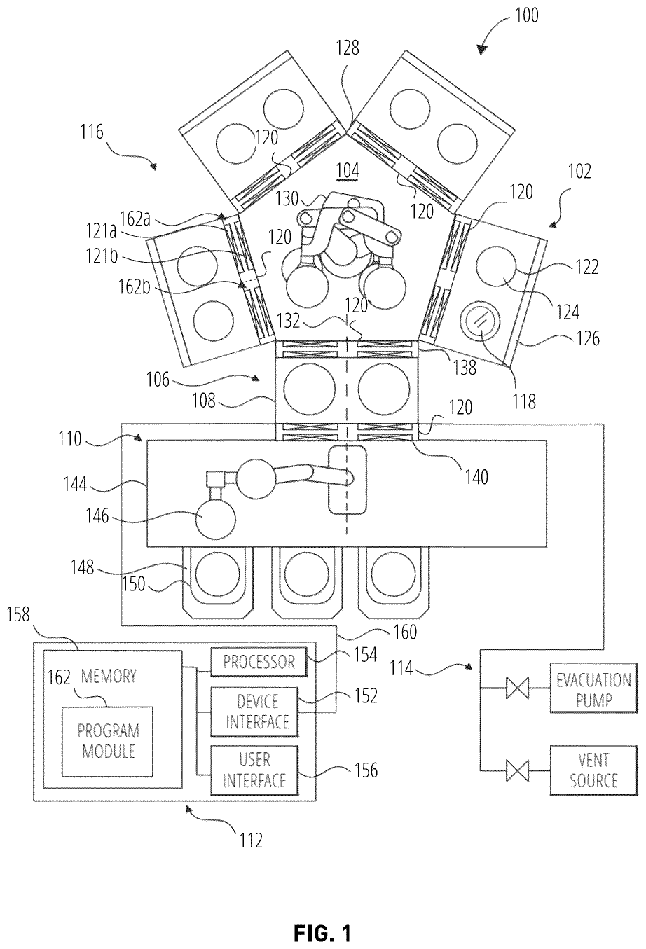

Turning now to the figures, FIG. 1 illustrates a reactor system 100 of the present disclosure, including a number of gate valve assemblies 120 including dual gate valve devices (e.g., gate valve devices 121a and 121b) and substrate sensing devices (not illustrated in FIG. 1) as described in detail below. The reactor system 100 includes a process module 102, a back-end transfer module 104, and a load lock arrangement 106 including load lock body 108. The reactor system 100 also includes an equipment front-end module 110 (EFEM), a controller 112, and a vacuum assembly 114 including an evacuation pump and venting source. In the illustrated example the reactor system 100 includes a cluster-type platform 116 with four (4) process modules configured to deposit/etch a material layer onto/from a substrate 118 using deposition and/or etch processes, such as, atomic layer deposition (ALD), chemical vapor deposition (CVD), plasma-enhanced chemical vapor deposition (PECVD), plasma-enhanced atomic layer deposition (PEALD), atomic layer etch (ALEt) processes, chemical vapor etch (CVE) processes, and plasma based dry-etch processes, for example. This is for illustration and description purposes only and is non-limiting. As will be appreciated by those of skill in the art in view of the present disclosure, reactor systems configured for other material layer deposition/etch operations as well as reactor systems configured for other processing operations can also benefit from the present disclosure.

The process module 102 can be coupled to the back-end transfer module 104 by one or more gate valve assemblies 120 each of which can include dual gate valve devices (e.g., gate valve devices 121a and 121b). In various embodiments the process module 102 can be coupled to the back-end transfer module 104 by two gate valve assemblies where each gate valve assembly includes dual gate valves, as illustrated by dual gate valve assemblies 162a and 162b.

The process module 102 can include a process chamber 122, a heater 124, and a reactant source 126. The process chamber 122 is arranged within the process module 102, houses the heater 124, and is configured to flow a precursor or reactant across the substrate 118 while seated on the heater 124 during deposition/etch of a material layer onto/from the substrate 118. The precursor/reactant source 126 is fluidly coupled to the process chamber 122 and configured to provide the precursor/reactant to the process chamber 122 for deposition/etch of the one or more material layers onto/from the substrate 118. The gate valve assembly 120 couples the process module 102 to the back-end transfer module 104 and is configured to provide selective communication between the process chamber 122 and the back-end transfer module 104. In this respect it is contemplated that the gate valve assembly 120 can be configured to permit transfer of the substrate 118 between the back-end transfer module 104 and the process module 102 before and after deposition/etch of material layer(s) onto/from the substrate 118.

In accordance with examples of the disclosure, the process chamber 122 may be a first process chamber and the process module 102 may include one or more second process chambers. For example, the process module 102 may be a dual chamber module having two (2) process chambers or a quad chamber module having four (4) process chambers. It is contemplated that, in certain examples, the reactant may include a reactant or a precursor suitable for deposition/etch of a material layer. It is also contemplated that, in accordance with certain examples, the process module 102 includes a plasma unit configured to provide the reactant from reactant source 126 to the substrate 118 as a suitable plasma. In this respect the process module 102 may be configured to deposit/etch a material layer onto/from the substrate 118 using a plasma-enhanced deposition/etch technique by way of example.

The back-end transfer module 104 is coupled to a rear face 138 of the load lock body 108 and includes a back-end chamber body 128 and a back-end substrate transfer robot 130. The back-end chamber body 128 is arranged along a transfer axis 132. It is contemplated that the back-end substrate transfer robot 130 can be arranged within an interior of the back-end chamber body 128 and supported within the back-end chamber body 128 for movement relative to the back-end chamber body 128 for transfer of substrates, e.g., the substrate 118, between the load lock arrangement 106 and the process module 102. In certain examples, the back-end chamber body 128 may have a polygonal shape. In this respect the back-end chamber body 128 may have five sides, fewer than five sides (e.g., a rectangular or square shape), or more than five sides (e.g., a hexagonal shape), and may have the shape of a regular polygon or an irregular polygon.

The equipment front-end module 110 can be coupled to a front face 140 of the load lock body 108 and includes an enclosure 144, a front-end substrate transfer robot 146, and one or more load ports 148. The enclosure 144 houses the front-end substrate transfer robot 146. The front-end substrate transfer robot 146 is housed within the enclosure 144 for movement relative to the enclosure 144 or transfer of substrates, e.g., the substrate 118, between the one or more load ports 148 and the load lock arrangement 106. The one or more load ports 148 are connected to the enclosure 144 and are configured to seat therein a pod 150 housing one or more substrates, prior to and subsequent to deposition/etch of material layers onto/from the substrates. In certain examples, the pod(s) 150 may include a standard mechanical interface pod. In accordance with certain examples, the pod(s) 150 may include a front-opening unified pod. Although shown and described herein as having three (3) load ports it is to be understood and appreciated that equipment front-end module 110 may include fewer or additional load ports and remain within the scope of the present disclosure.

The controller 112 is operably connected to the reactor system 100 and includes a device interface 152, a processor 154, a user interface 156, and a memory 158. The device interface 152 couples the processor 154 to the reactor system 100, for example, through (or over) a wired or wireless link 160. The processor 154 is operably connected to the user interface 156 and is disposed in communication with the memory 158. The memory 158 includes a non-transitory machine-readable medium having a plurality of program modules 162 recorded thereon containing instructions that, when read by the processor 154, cause the processor 154 to execute certain operations. The controller 112 can be employed to perform the methods of the present disclosure utilizing the reactor system 100. For example, the controller 112 can be employed to perform parallel operations within the gate valve assemblies 120 of the reactor system 100 as described in detail below.

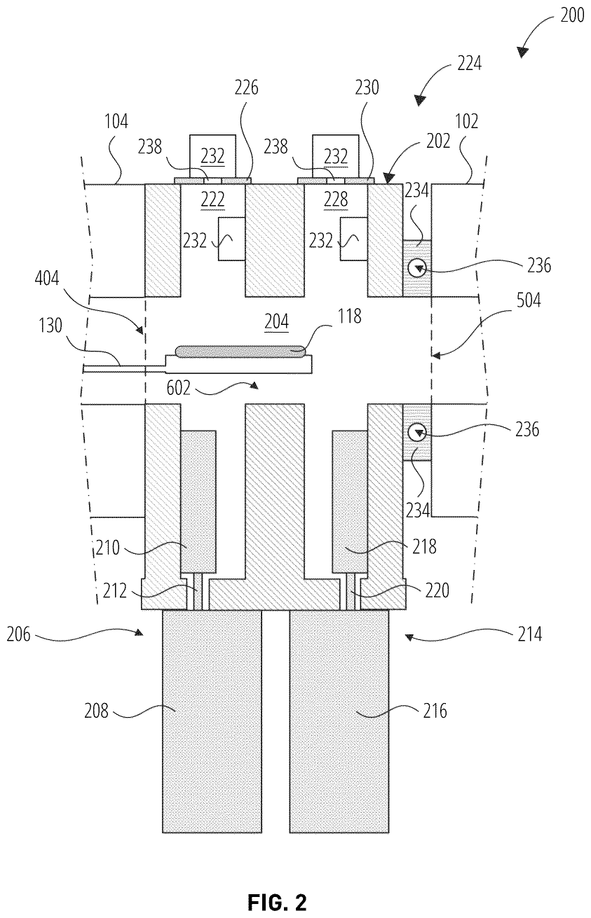

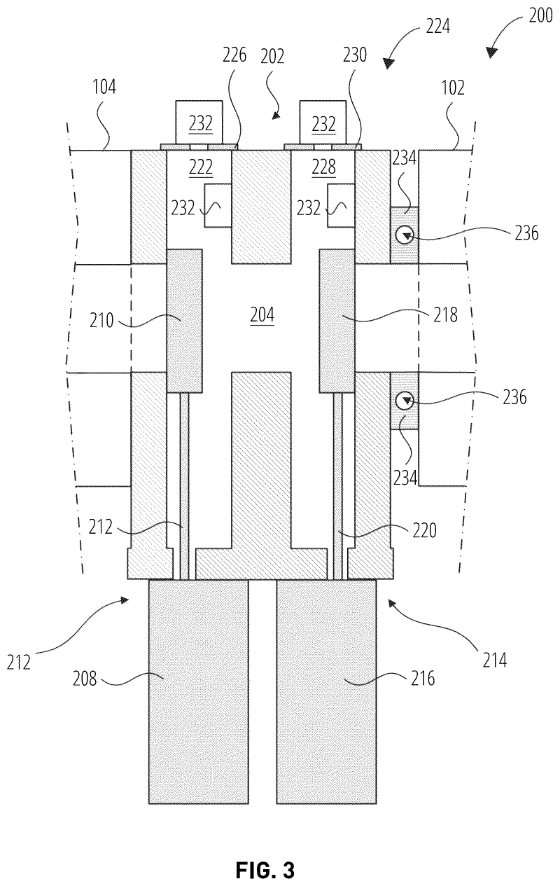

FIG. 2 and FIG. 3 illustrate cross-sectional views of a portion of reactor system 200 (similar to or the same as that of reactor system 100 of FIG. 1) including a gate valve assembly 224 of the present disclosure. For example, FIG. 2 illustrates the gate valve assembly 224 with the sealing members (210 and 218) in the open position and FIG. 3 illustrates the gate valve assembly 224 with the sealing members in the closed position, as described in greater detail below.

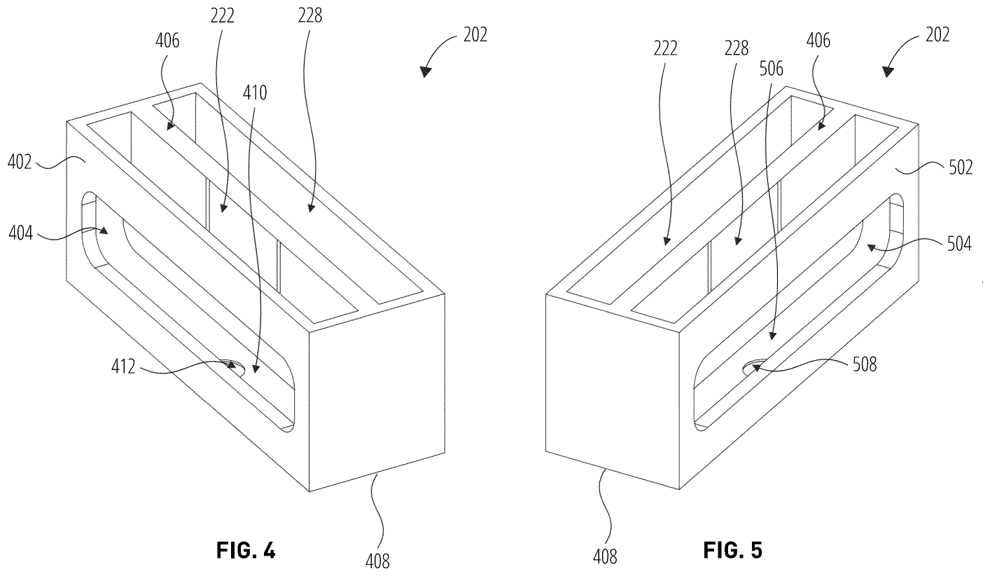

In accordance with examples of the disclosure, the reactor system 200 (FIG. 2 and FIG. 3) includes a gate valve assembly 224 which comprises a gate valve block body 202, as described in greater detail below with reference to FIG. 4 to FIG. 6. In such examples the gate valve block body 202 can comprise a singular block body and a passthrough 204. In some embodiments the passthrough 204 can be sized and arranged to allow the transfer of a substrate 118 from a back-end transfer module 104 through the gate valve block body 202 to a process module 102 employing a back-end substrate transfer robot 130, for example. The reactor system 200 can further comprises a first gate valve device 206 which comprises a first gate valve actuator 208 which is mechanical coupled to a first sealing member 210 by a first actuating member 212. The reactor system 200 can further comprise a second gate valve device 214 which comprising a second gate valve actuator 216 which is mechanically coupled to a second sealing member 218 by a second actuating member 220. The first gate valve actuator 208 along with the first actuating member 212 are configured to move the first sealing member 210 between a first open position (as illustrated in FIG. 2) and a first closed position (as illustrated in FIG. 3). Likewise, the second gate valve actuator 216 along with the second actuating member 220 are configured to move the second sealing member 218 between a second open position (as illustrated in FIG. 2) and a second closed position (as illustrated in FIG. 3).

In accordance with examples of the disclosure, the gate valve assembly 224 comprises a first service channel 222 disposed within gate valve block body 202 and enclosed by a first removable service cover 226 (as described in detail below). The gate valve assembly 224 further comprise a second service channel 228 disposed within gate valve block body 202 and enclosed by a second removable service cover 230 (as described in detail below).

In accordance with examples of the disclosure, the gate valve assembly 224 of reactor systems 200 can further comprise one or more sensor assemblies 232. In some embodiments the sensor assemblies 232 can be disposed externally on a top surface of the first and/or second removable service covers (226 and 230). In some embodiments the sensor assemblies 232 can be disposed internally within at least one of the first service channel 222 and/or the second service channel 228. Details regarding the sensor assemblies 232 and their functionality and positioning is described in greater detail below.

In accordance with examples of the disclosure, the reactor system 200 can further comprise a flange assembly 234. In such examples the flange assembly 234 can be configured to couple the gate valve block body 202 to the process module 102. In such examples the flange assembly 234 may further comprise an internal cooling channel 236 for providing temperature control to the flange assembly 234.

In further examples, the gate valve block body 202 and the flange assembly 234 are integrated to form an integrated gate valve assembly including both elements. In such an example, the gate valve block body 202 can be fabricated from aluminum and the integrated flange assembly 234 can be fabricated from a stainless steel material. Such an integrated gate valve assembly (including both the gate valve block body and the flange assembly) can have a reduced overall weight without compromising the cooling capability of the integrated assembly. For example, the stainless steel material of the integrated flange assembly can control the overall heat transfer from the process module 102, as it has a lower thermal conductivity and in addition can protect the internal cooling channels 236 from corrosion. In addition, the stainless steel construction of the integrated flange assembly may require no addition surface treatments and can reduce the complexity of fabricating of the internal cooling channels 236 within the flange assembly portion of the integrated gate valve assembly.

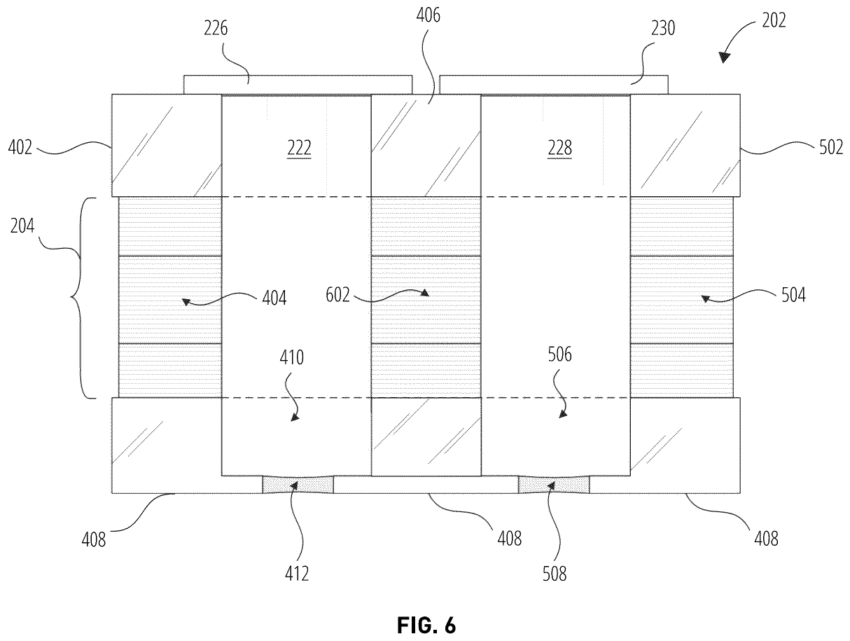

FIG. 4, FIG. 5, and FIG. 6 illustrate different views of a gate valve block body of the gate valve assemblies of the disclosure. FIG. 4 and FIG. 5 illustrate perspective views of the gate valve block body 202 and FIG. 6 illustrates a cross sectional view of the gate valve block body 202.

In accordance with examples of the disclosure and with reference to FIG. 4 to FIG. 6, the gate valve block body 202 comprises a first face 402 having a first lateral aperture 404. The gate valve block body 202 further comprise a second face 502 longitudinally spaced apart from the first face 402 and having a second lateral aperture 504. The gate valve block body 202 can further comprise an intermediate member 406 disposed between the first face 402 and the second face 502, the intermediate member 406 comprising a third lateral aperture 602 (FIG. 6). The gate valve block body 202 further comprises a passthrough 204 that extends through the gate valve block body 202 (see for example FIG. 2 and FIG. 6). In such examples, the passthrough 204 extends through the gate valve block body 202 coupling the first lateral aperture 404 to the third lateral aperture 602 (i.e., extending through the intermediate member 406) and the second lateral aperture 504. The passthrough 204 (and the associated first lateral aperture 404, third lateral aperture 602, and second lateral aperture 504) can be sized and arranged to allow the transfer of a substrate through the gate valve block body 202. For example, a substrate 118 (FIG. 2) can be inserted through the first lateral aperture 404 (e.g., by the back-end substrate transfer robot 130) and transferred through the third lateral aperture 602 and extracted from the gate valve block body 202 via the second lateral aperture 504 (or vice versa).

In accordance with examples of the disclosure, the gate valve block body 202 can further comprise a block body floor 408 extending between the first face 402 and the second face 502. In such examples the intermediate member 406 intersects the block body floor 408 (FIG. 6). In accordance with examples of the disclosure, the first face 402, the intermediate member 406 and the block body floor 408 at least partially define a first valve seat 410 (FIG. 6). In addition, the second face 502, the intermediate member 406, and the block body floor 408 at least partially defines a second valve seat 506 (FIG. 6). As used herein, a “valve seat” refers to a region internally within the gate valve block body 202 wherein a sealing member of a gate valve device can residue.

In accordance with examples of the disclosure, a first aperture 412 is disposed in the first valve seat 410. In such examples the first aperture 412 can be disposed at the base of the first valve seat 410. In some embodiments the first aperture 412 extends through the block body floor 408, i.e., the first aperture 412 extends from a top surface of the block body floor 408 down and through the block body floor 408 to allow access from the bottom of the gate valve block body 202 into the first valve seat 410. In such embodiments the first aperture 412 is sized and configured for receiving a first actuating member (e.g., 212 of FIG. 2) of a first gate valve actuator (e.g., 208 of FIG. 2), as described with reference to FIG. 2 and FIG. 3.

In accordance with examples of the disclosure, a second aperture 508 is disposed in the second valve seat 506. In such examples the second aperture 508 can be disposed at the base of the second valve seat 506. In some embodiments the second aperture 508 extends through the block body floor 408, i.e., the second aperture 508 extends from a top surface of the block body floor 408 down and through the block body floor 408 to allow access from the bottom of the gate valve block body 202 into the second valve seat 506. In such embodiments the second aperture 508 is sized and configured for receiving a second actuating member (e.g., 220 of FIG. 2) of a second gate valve actuator (e.g., 216 of FIG. 2), as described with reference to FIG. 2 and FIG. 3.

In accordance with examples of the disclosure, the gate valve block body 202 can comprise a singular block body. In such examples the gate valve block body 202 extends monolithically between the first face 402 of the gate valve block body 202 and the second face 502 of the gate valve block body 202. In such examples the singular block body can comprise a single metallic block manufactured from aluminum, for example. In such examples the first face 402, the second face 502, the intermediate member 406, the block body floor 408, and the sidewalls of the gate valve block body 202 comprise a singular block body. In such examples the first lateral aperture 404, the second lateral aperture 504, the third lateral aperture 602, and the first and second apertures (412 and 508) are formed within the singular block body.

In accordance with examples of the disclosure, gate valve assemblies of the present disclosure and particularly the gate valve block body 202 further comprises a first service channel 222, as previously illustrated in FIG. 2 and FIG. 3. In more detail and with reference to FIG. 6 the first service channel 222 can be disposed between an upper portion of the first face 402 and the intermediate member 406. In addition, the gate valve block body 202 further comprises a second service channel 228, the second service channel 228 being disposed between an upper portion of the second face 502 and the intermediate member 406. In accordance with examples of the disclosure, the first service channel 222 and the second service channel 228 can be sized and arranged to allow for case of access to the interior of the gate valve block body thereby simplifying maintenance of gate valve assemblies including the gate valve block body 202. In addition, and as described below, the first service channel 222 and the second service channel 228 can further be utilized to add additional functionality to the gate valve assemblies of the present disclosure.

The gate valve assemblies of the present disclosure can further comprise one or more of removable service covers, as previously illustrated in FIG. 2 and FIG. 3. In such examples and with reference to FIG. 6, a first removable service cover 226 can extend between an upper surface of the first face 402 and an upper surface of the intermediate member 406 thereby enclosing the first service channel 222. In addition, a second removable service cover 230 can extend between an upper surface of the second face 502 and the upper surface of the intermediate member 406 thereby enclosing the second service channel 228.

In accordance with examples of the disclosure, the gate valve assemblies of the present disclosure can further include the addition of one or more sensor assemblies to enable monitoring and/or control of the properties/conditions within the interior of the gate valve assembly, e.g., within the interior of the gate valve block body. In some embodiments the sensor assemblies can be utilized to determine the properties of a substrate as it is transferred through the gate valve assembly as briefly described above with reference to FIG. 2 and FIG. 3.

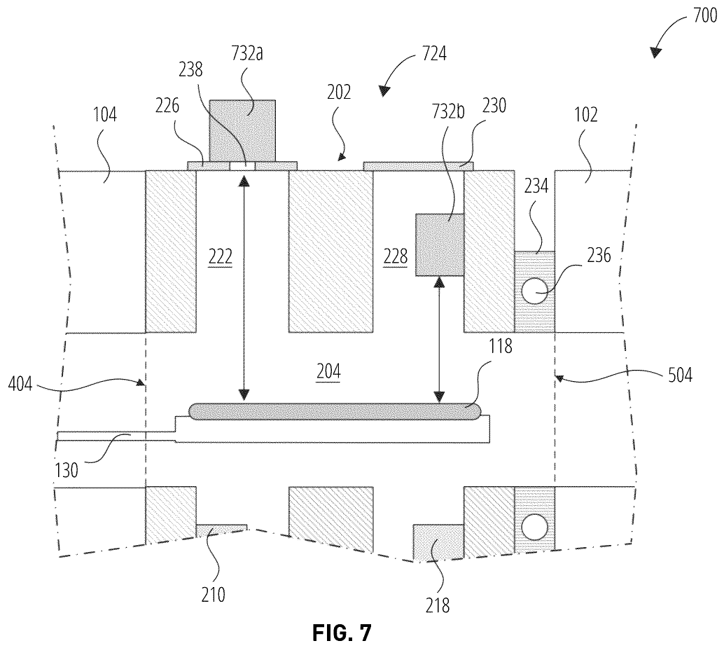

In more detail, FIG. 7 illustrates a reactor system 700 and includes an expanded view of a portion of a gate valve assembly 724 (similar to that illustrated in FIG. 2) where the region in and around the passthrough 204 and the substrate 118 disposed therein is expounded. It should be noted that as illustrated in FIG. 7, both the first sealing member 210 (of the first gate valve device) and the second sealing member 218 (of the second gate valve device) are in the open position to allow the transfer of the substrate 118 via the back-end substrate transfer robot 130. The gate valve assembly 724 can be disposed between and interface with a back-end transfer module 104 and a process module 102. The back-end substrate transfer robot 130 can be employed to transfer a substrate 118 between the back-end transfer module 104 and the process module 102 through the passthrough 204 within the gate valve assembly 724. As the substrate 118 is transferred through the passthrough 204, one or more sensor assemblies (e.g., 732a and 732b) can be employed to determine the properties of the substrate 118. In such embodiments each of the sensor assemblies can comprise multiple sensing devices. For example, each of the sensor assemblies can include multiple sensing devices configured for determining the surface properties of the substrate 118 at various substrate surface positions.

In various embodiments the gate valve assembly 724 can include sensor assemblies (e.g., 732a and 732b) that are each aligned with at least one of the first service channel 222 and the second service channel 228, as illustrated in FIG. 7.

In some embodiments the sensor assemblies can be disposed internally within the gate valve assembly 724, e.g., within the gate valve block body 202. In such embodiments the sensor assemblies can be disposed internally within at least one of the first service channel 222 and the second service channel 228, as illustrated by exemplary internal sensor assemblies 732b.

In some embodiments the sensor assemblies can be disposed externally on the gate valve assembly 724. In such embodiments the sensor assemblies can be disposed externally on at least one of a top surface the first removable service cover 226 and/or a top surface of the second removable service cover 230, as illustrated by exemplary external sensor assembly 732a. In addition, when the sensor assemblies are positioned externally on the top surface of either one of the removable service covers (226 and 230), at least one of the first removable service cover 226 and the second removable service cover 230 can further comprise a view port, such as exemplary view port 238 of FIG. 7. For example, the sensor assemblies can include sensing device(s) which can determine the properties of the substrate by emitting an optical signal and subsequently receiving a reflected optical signal reflected from a surface of the substrate, the reflected optical signal indicating a property of the substrate when compared with the emitted optical signal. In such examples one or more of the first removable service cover 226 and the second removable service cover 230 can include a view port that allows the transmission of both the emitted and reflected optical signals. The view port can comprise an optically transparent material having optical transparency over at least a portion of a wavelength that is emitted and/or received by the sensor assemblies, such as external sensor assembly 732a, for example. As a non-limiting example, the view port 238 may comprise a quartz material or a sapphire material.

In accordance with examples of the disclosure, each one of the one or more sensor assemblies (e.g., sensor assemblies 732a and 732b) can comprise an automatic substrate centering sensor configured to detect misalignment of a substrate as it is transferred through the passthrough 204. Common cluster-type platforms can include automatic substrate centering sensors to detect substrate centering on the back-end substrate transfer robot 130 (e.g., on the end effector of the robot). However, automatic substrate centering sensors employed in prior cluster-type platforms can require that the back-end transfer module 104 be partially disassembled to service the automatic substrate centering sensors. Such partial disassembly and reassembly of the back-end transfer module 104 during servicing of the automatic substrate centering sensors limits the through-put of substrates through the cluster-type platform by requiring that the entire cluster-type platform, and each of the associated process modules, is taken out of production in the event that any one of the automatic substrate centering sensors needs service and/or repair.

In accordance with further examples of the disclosure, each one of the one or more sensor assemblies (e.g., sensor assemblies 732a and 732b) can comprise a substrate deformation sensor. In such examples the substrate deformation sensor(s) can be employed to measure thermally induced deformation of the substrate. In various embodiments the substrate deformation sensor can comprise an array of 2D distance measuring sensors or a laser profiling instrument. In one aspect the substrate deformation data received from the substrate deformation sensor can be combined with the linear motion of the substrate through the passthrough 204 to create a 3D topographical map of the substrate. In such aspects the linear motion (and the linear motion data) is provided by the back-end substrate transfer robot 130. In such embodiments the substrate deformation sensor can determine the deformation of the substrate at an elevated temperature within a vacuum environment. Enabling substrate deformation measurements within the gate valve arrangements of the present disclosure provides a distinct advantage over ex-situ measurement sensors, e.g., off-line sensors and measurement tools external to the reactor system.

In one example, a line scanner can be mounted externally on one or more of the removeable service covers (226, 230), and a window (e.g., view ports 238) can be added to one or more of the removeable service covers, such that the liner scanner can detect wafer bow as a substrate passes through the dual gate valve assembly 224. Positioning a line scanner externally avoids competing with internal sensors that may be located within the gate valve assembly 224, simplifying packaging and maintenance. In addition, externally mounting a line scanner can simplify the maintenance of the line scanner by avoiding the need to open the gate valve assembly 224 for service. In another examples, a line scanner can be mounted from an interior surface of one of more of the service channels (222, 228) and can be disposed above the transfer path of the substrate through the dual gate valve assembly 224.

The various embodiments of the disclosure also include methods for performing parallel operation within a reactor system including the gate valve assemblies as previously described. In such embodiments the gate valve assemblies include one or more sensor assemblies which allow for the monitor and/or control of a substrate as the substrate is transferred through the passthrough within the gate valve block body of the gate valve assembly.

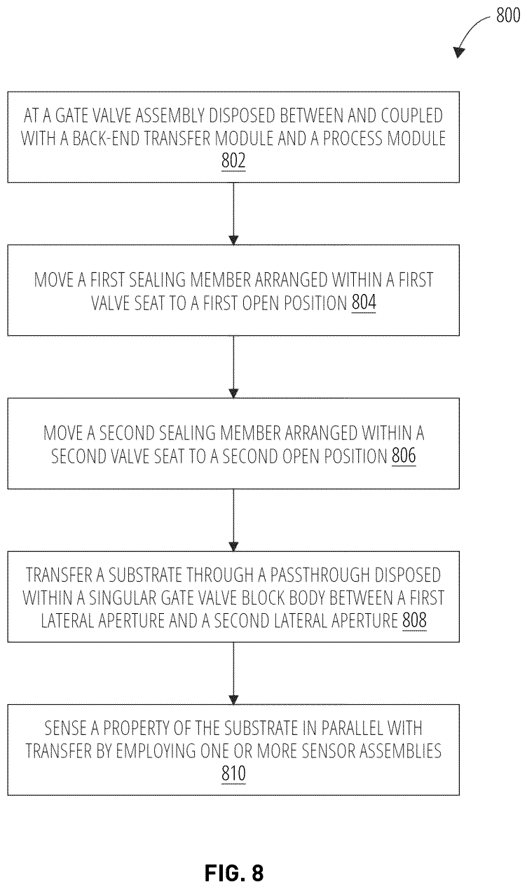

FIG. 8 illustrates a method 800 for performing parallel operations within a gate valve assembly positioned between a back-end transfer module and a process module where the gate valve assembly includes one or more sensor assemblies.

In accordance with examples of the disclosure, a step 802 of the method 800 comprises, at a gate valve assembly (such as gate valve assemblies 224 and 724 of FIG. 2 and FIG. 7 respectively, for example) which is disposed between and coupled with a back-end transfer module and a process module, i.e., as illustrated by reactor system 200 of FIG. 2. In such examples the gate valve assembly can comprise a singular gate valve block body which comprises a first face with a first lateral aperture, a second face longitudinally spaced apart from the first face and having a second lateral aperture, and an intermediate member disposed between the first face and the second face, the intermediate member having a third lateral aperture. In some embodiments the gate valve assembly can further comprise a block body floor extending between the first face and the second face. In such embodiments the intermediate member can intersect the block body floor. In some embodiments the first face, the intermediate member and the block body floor at least partially define a first valve seat and the second face, the intermediate member and the block body floor at least partially define a second valve seat. In some embodiments the gate valve assembly can further comprise a first aperture disposed in the first valve seat and configured for receiving a first actuating member of a first gate valve actuator. In some embodiments the gate valve assembly can further comprise a second aperture disposed in the second valve seat and configured for receiving a second actuating member of a second gate valve actuator. In some embodiments the gate valve assembly can further comprise a passthrough extending through the singular gate valve block body and coupling the first lateral aperture to the third lateral aperture and the second lateral aperture.

In accordance with examples of the disclosure, the method 800 of FIG. 8 can also include a step 804 which comprises, moving a first sealing member arranged within the first valve seat from a first closed position (as illustrated in FIG. 3), whereat the first sealing member separates the first lateral aperture from the second lateral aperture, to a first open position (as illustrated in FIG. 2), whereat the first lateral aperture is fluidly coupled to the second valve seat. In such examples the first gate valve actuator is operably connected to the first sealing member by the first actuating member and is configured to move the first sealing member from the first closed position to the first closed position by movement of the first actuating member through the first aperture.

In accordance with examples of the disclosure, the method 800 of FIG. 8 can also include a step 806 which comprises, moving a second sealing member arranged within the second valve seat from a second closed position (as illustrated in FIG. 3), whereat the second sealing member separates the first lateral aperture from the second lateral aperture, to a second open position (as illustrated in FIG. 2), whereat the first lateral aperture is fluidly coupled to the second valve seat. In such examples the second gate valve actuator is operably connected to the second sealing member by the second actuating member and is configured to move the second sealing member from the second closed position to the second closed position by movement of the second actuating member through the second aperture.

In accordance with examples of the disclosure, the method 800 of FIG. 8 can further include a step 808 which comprises, transferring a substrate through the passthrough disposed within the singular gate valve block body between the first lateral aperture and the second lateral aperture. In such examples a back-end substrate transfer robot (as illustrated by back-end substrate transfer robot 130 in FIG. 2, FIG. 3, and FIG. 7) can be employed to transfer a substrate 118 through the passthrough 204. In some embodiments the substrate 118 can be transferred from the back-end transfer module 104, through the passthrough 204, to the process module 102. In some embodiments the substrate 118 can be transferred from the process module 102, through the passthrough 204, to the back-end transfer module 104. In some embodiments one or more substrates may be transferred simultaneously through the passthrough 204.

In one aspect transferring the substrate through the passthrough comprises a continuous linear motion of the substrate through the passthrough. In such aspects the back-end substrate transfer robot 130 can be configured to move the substrate 118 with a continuous motion through the passthrough 204.

In another aspect transferring the substrate through the passthrough comprises a discontinuous linear motion of the substrate through the passthrough. In such aspects the back-end substrate transfer robot 130 can be configured to move the substrate 118 through the passthrough 204 with a discontinuous motion. For example, the speed of the motion of the substrate 118 through the passthrough 204 can be decreased and/or increased, or even halted as the substrate is transferred. In some embodiments the speed of the motion of the substrate 118 may be reduced or even reduced to zero (i.e., stopped) when employing the sensor assemblies (e.g., 732a and 732b of FIG. 7) to monitor and/or control the substrate 118 within the passthrough 204. As used herein the term “transfer” and “transferring” can refer to both continuous and discontinuous motion of a substrate through the passthrough of the gate valve assembly.

In accordance with examples of the disclosure, the method 800 of FIG. 8 can further comprise a step 810 which comprises, sensing a property of the substrate in parallel with transferring the substrate. In such examples the step 810 can comprise sensing a property of the substrate during transfer by employing the one or more sensor assemblies (e.g., sensor assemblies 732a and 732b of FIG. 7). In such examples each of the sensor assemblies can be aligned with at least one of a first service channel disposed between an upper portion of the first face and the intermediate member and a second service channel disposed between an upper portion of the second face and the intermediate member. In some embodiments the one or more sensor assemblies comprise an automatic substrate centering sensor configured to detect substrate misalignment. In some embodiments the one or more sensor assemblies comprise a substrate deformation sensor configured to detect substrate bow.

In various embodiments the step 810 of method 800 can further comprise sensing one or more (e.g., multiple) properties of the substrate as the substrate is transferred through the passthrough of the gate valve assembly. In some embodiments the one or more properties of the substrate may be sensed simultaneously, or with at least some temporal overlap, by employing multiple sensor assemblies and/or a sensor assembly including multiple individual sensing devices.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A gate valve assembly comprising:
a gate valve block body comprising:
a first face with a first lateral aperture;
a second face longitudinally spaced apart from the first face and having a second lateral aperture;
an intermediate member disposed between the first face and the second face, the intermediate member having a third lateral aperture;
a block body floor extending between the first face and the second face, wherein the intermediate member intersects the block body floor, and wherein the first face, the intermediate member and the block body floor at least partially define a first valve seat and the second face, the intermediate member and the block body floor at least partially define a second valve seat;
a first aperture disposed in the first valve seat and configured for receiving a first actuating member of a first gate valve actuator;
a second aperture disposed in the second valve seat and configured for receiving a second actuating member of a second gate valve actuator; and
a passthrough extending through the gate valve block body and coupling the first lateral aperture to the third lateral aperture and the second lateral aperture,
wherein the gate valve block body comprises a singular gate valve block body which extends monolithically between the first face and the second face.

2. The gate valve assembly of claim 1, further comprising a flange assembly coupled to the first face and configured to couple the gate valve block body with a process module of a reactor system.

3. The gate valve assembly of claim 2, further comprising a first service channel disposed between an upper portion of the first face and the intermediate member and a second service channel disposed between an upper portion of the second face and the intermediate member.

4. The gate valve assembly of claim 3, further comprising a first removable service cover extending between an upper surface of the first face and an upper surface of the intermediate member and enclosing an upper extent of the first service channel, and a second removable service cover extending between an upper surface of the second face and the upper surface of the intermediate member and enclosing an upper extent of the second service channel.

5. The gate valve assembly of claim 4, further comprising one or more sensor assemblies each aligned with at least one of the first service channel and the second service channel and configured for sensing a substrate property as a substrate traverses the passthrough between the first lateral aperture and the second lateral aperture.

6. The gate valve assembly of claim 5, wherein the one or more sensor assemblies comprise an automatic substrate centering sensor configured to detect misalignment of a substrate as a substrate traverses the passthrough.

7. The gate valve assembly of claim 5, wherein the one or more sensor assemblies comprise a substrate deformation sensor configured to detect substrate bow as a substrate traverses the passthrough.

8. The gate valve assembly of claim 5, wherein at least one of the one or sensor assemblies is positioned internally within at least one of the first service channel and the second service channel.

9. The gate valve assembly of claim 5, wherein at least one of the one or more sensor assemblies is positioned externally on at least one of a top surface of the first removable service cover and a top surface of the second removable service cover.

10. The gate valve assembly of claim 9, wherein at least one of the first removable service cover and the second removable service cover comprises a view port, wherein the view port comprises an optically transparent material having optical transparency over at least a portion of a wavelength that is emitted and/or received by one of the sensor assemblies.

11. The gate valve assembly of claim 1, further comprising:
a first sealing member arranged within the first valve seat and having a first closed position, whereat the first sealing member separates the first lateral aperture from the second lateral aperture, and a first open position, whereat the first lateral aperture is fluidly coupled to the second valve seat;
the first gate valve actuator operably connected to the first sealing member by the first actuating member and configured to move the first sealing member between the first open position and the first closed position by movement of the first actuating member through the first aperture;
a second sealing member arranged within the second valve seat and having a second closed position, whereat the second sealing member separates the first lateral aperture from the second lateral aperture, and a second open position, whereat the first valve seat is fluidly coupled to the second lateral aperture; and
the second gate valve actuator being operably connected to the second sealing member and configured to move the second sealing member between the second open position and the second closed position by movement of the second actuating member through the second aperture.

12. A reactor system comprising:
a back-end transfer module;
a process module; and
a gate valve assembly disposed between and coupled with the back-end transfer module and the process module, the gate valve assembly comprising:
a gate valve block body comprising:
a first face with a first lateral aperture;
a second face longitudinally spaced apart from the first face and having a second lateral aperture;
an intermediate member disposed between the first face and the second face, the intermediate member having a third lateral aperture;
a block body floor extending between the first face and the second face, wherein the intermediate member intersects the block body floor, and wherein the first face, the intermediate member and the block body floor at least partially define a first valve seat and the second face, the intermediate member and the block body floor at least partially define a second valve seat;
a first aperture disposed in the first valve seat and configured for receiving a first actuating member of a first gate valve actuator;
a second aperture disposed in the second valve seat and configured for receiving a second actuating member of a second gate valve actuator; and
a passthrough extending through the gate valve block body and coupling the first lateral aperture to the third lateral aperture and the second lateral aperture;
a first sealing member arranged within the first valve seat and having a first closed position, whereat the first sealing member separates the first lateral aperture from the second lateral aperture, and a first open position, whereat the first lateral aperture is fluidly coupled to the second valve seat;
the first gate valve actuator operably connected to the first sealing member by the first actuating member and configured to move the first sealing member between the first open position and the first closed position by movement of the first actuating member through the first aperture;
a second sealing member arranged within the second valve seat and having a second closed position, whereat the second sealing member separates the first lateral aperture from the second lateral aperture, and a second open position, whereat the first valve seat is fluidly coupled to the second lateral aperture;
the second gate valve actuator operably connected to the second sealing member and configured to move the second sealing member between the second open position and the second closed position by movement of the second actuating member through the second aperture; and
a flange assembly coupled to the first face and configured to couple the gate valve block body with the process module;
wherein the gate valve block body comprises a singular gate valve block body which extends monolithically between the first face and the second face.

13. The reactor system of claim 12, further comprising a first service channel disposed between an upper portion of the first face and the intermediate member and a second service channel disposed between an upper portion of the second face and the intermediate member.

14. The reactor system of claim 13, further comprising a first removable service cover extending between an upper surface of the first face and an upper surface of the intermediate member and enclosing an upper extent of the first service channel, and a second removable service cover extending between an upper surface of the second face and the upper surface of the intermediate member and enclosing an upper extent of the second service channel.

15. The reactor system of claim 14, further comprising one or more sensor assemblies each aligned with at least one of the first service channel and the second service channel and configured for sensing a substrate property as substrate traverses the passthrough disposed between the first lateral aperture and the second lateral aperture.

16. The reactor system of claim 15, wherein the one or more sensor assemblies comprise an automatic substrate centering sensor configured to detect substrate misalignment as a substrate traverses the passthrough.

17. The reactor system of claim 15, wherein the one or more sensor assemblies comprise a substrate deformation sensor configured to detect substrate bow as a substrate traverses the passthrough.

18. A method of performing parallel operations within a gate valve assembly including one or more sensor assemblies, the method comprising:
at the gate valve assembly disposed between and coupled with a back-end transfer module and a process module, the gate valve assembly comprising a singular gate valve block body comprising:
a first face with a first lateral aperture;
a second face longitudinally spaced apart from the first face and having a second lateral aperture;
an intermediate member disposed between the first face and the second face, the intermediate member having a third lateral aperture;
a block body floor extending between the first face and the second face, wherein the intermediate member intersects the block body floor, and wherein the first face, the intermediate member and the block body floor at least partially define a first valve seat and the second face, the intermediate member and the block body floor at least partially define a second valve seat;
a first aperture disposed in the first valve seat and configured for receiving a first actuating member of a first gate valve actuator;
a second aperture disposed in the second valve seat and configured for receiving a second actuating member of a second gate valve actuator; and
a passthrough extending through the singular gate valve block body and coupling the first lateral aperture to the third lateral aperture and the second lateral aperture;
moving a first sealing member arranged within the first valve seat and from a first closed position, whereat the first sealing member separates the first lateral aperture from the second lateral aperture, to a first open position, whereat the first lateral aperture is fluidly coupled to the second valve seat, wherein the first gate valve actuator is operably connected to the first sealing member by the first actuating member and is configured to move the first sealing member from the first closed position to the first closed position by movement of the first actuating member through the first aperture;
moving a second sealing member arranged within the second valve seat and from a second closed position, whereat the second sealing member separates the first lateral aperture from the second lateral aperture, to a second open position, whereat the first lateral aperture is fluidly coupled to the second valve seat, wherein the second gate valve actuator is operably connected to the second sealing member by the second actuating member and is configured to move the second sealing member from the second closed position to the second closed position by movement of the second actuating member through the second aperture;
transferring a substrate through the passthrough disposed within the singular gate valve block body between the first lateral aperture and the second lateral aperture; and
sensing a property of the substrate in parallel with transferring the substrate by employing the one or more sensor assemblies which are each aligned with at least one of a first service channel disposed between an upper portion of the first face and the intermediate member and a second service channel disposed between an upper portion of the second face and the intermediate member.

19. The method of claim 18, wherein the one or more sensor assemblies comprise an automatic substrate centering sensor configured to detect substrate misalignment.

20. The method of claim 18, wherein the one or more sensor assemblies comprise a substrate deformation sensor configured to detect substrate bow.
